(19) United States
(12) Patent Application Publication
(10) Pub. No.: US 2021/0238742 A1
(43) Pub. Date: Aug. 5, 2021

(54) METHOD OF FORMING A STRUCTURE INCLUDING CARBON MATERIAL, STRUCTURE FORMED USING THE METHOD, AND SYSTEM FOR FORMING THE STRUCTURE

(71) Applicant: ASM IP Holding B.V., Almere (NL)

(72) Inventors: Yoshio Susa, Tokyo (JP); Ryo Miyama, Tokyo (JP); Hirotsugu Sugiura, Tokyo (JP); Yoshiyuki Kikuchi, Tokyo (JP)

(21) Appl. No.: 17/166,660

(22) Filed: Feb. 3, 2021

Related U.S. Application Data
(60) Provisional application No. 62/970,483, filed on Feb. 5, 2020.

(51) Int. Cl. C23C 16/455; C23C 16/26

(52) U.S. Cl. CPC C23C 16/45538; C23C 16/26

(57) ABSTRACT

Methods and systems for forming a structure including carbon material and structures formed using the method or system are disclosed. Exemplary methods include providing an inert gas to the reaction chamber for plasma ignition, providing a carbon precursor to the reaction chamber, forming a plasma within the reaction chamber to form an initially viscous carbon material on a surface of the substrate, wherein the initially viscous carbon material becomes carbon material, and treating the carbon material with activated species to form treated carbon material.

### CROSS-REFERENCE TO RELATED APPLICATIONS

This application claims the benefit of U.S. Provisional Application No. 62/970,483, filed on Feb. 5, 2020, in the United States Patent and Trademark Office, the disclosure of which is incorporated herein in its entirety by reference.

### FIELD OF INVENTION

The present disclosure generally relates to methods of forming structures suitable for use in the manufacture of electronic devices. More particularly, examples of the disclosure relate to methods of forming structures that include a carbon material layer, to structures including such layers, and to systems for performing the methods and/or forming the structures.

### BACKGROUND OF THE DISCLOSURE

During the manufacture of devices, such as semiconductor devices, it is often desirable to fill features (e.g., trenches or gaps) on the surface of a substrate with insulating or dielectric material. Some techniques to fill features include the deposition of a layer of flowable carbon material.

Although use of carbon material to fill features can work well for some applications, filling features using traditional deposition techniques has several shortcomings, particularly as the size of the features to be filled decreases. For example, during deposition of carbon material, such as techniques that include plasma processes, voids can form within the deposited material, particularly within gaps. Such voids can remain even after reflowing the deposited material.

In addition to being flowable, it may be desirable for the carbon material to exhibit other properties, such as desired harness or modulus and/or etch selectivity relative to other material layers. As device and feature sizes continue to decrease, it becomes increasingly difficult to apply conventional carbon material deposition techniques to manufacturing processes, while obtaining desired fill capabilities and material properties. Further, various attempts to deposit carbon material on a surface of a substrate have led to undesirable amounts of particles on a substrate surface.

Accordingly, improved methods for forming structures, particularly for methods of filling gaps on a substrate surface with carbon material, that mitigate void formation in the carbon material and/or that provide desired carbon material properties and/or that produce fewer particles, are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

Various embodiments of the present disclosure relate to methods of forming structures (sometimes referred to herein as film structures) suitable for use in the formation of electronic devices. While the ways in which various embodiments of the present disclosure address drawbacks of prior methods and structures are discussed in more detail below, in general, exemplary embodiments of the disclosure provide improved methods for forming structures that include carbon material, structures including the carbon material, and systems for performing the methods and/or forming the structures. The methods described herein can be used to fill features on a surface of a substrate.

In accordance with various embodiments of the disclosure, methods of forming a structure are provided. Exemplary methods include providing a substrate within a reaction chamber, providing an inert gas to the reaction chamber, providing a carbon precursor to the reaction chamber, forming a plasma within the reaction chamber to form an initially viscous carbon material on a surface of the substrate, wherein the initially viscous carbon material becomes carbon material, and treating the carbon material with activated species to form treated carbon material. Exemplary methods can further include ceasing a flow of the carbon precursor to the reaction chamber and optionally ceasing the plasma. A carbon material deposition cycle can include the steps of providing a carbon precursor to the reaction chamber, forming a plasma within the reaction chamber to form an initially viscous carbon material on a surface of the substrate, wherein the initially viscous carbon material becomes carbon material, ceasing a flow of the carbon precursor to the reaction chamber, and ceasing the plasma. The carbon material deposition cycle can be performed a number of n times, where n can range from, for example, 0 to 50, prior to the step of treating the carbon material with activated species. A deposition and treatment cycle can include one or more carbon material deposition cycles and the step of treating the carbon material with activated species. The deposition and treatment cycle can be performed a number of N times, where N can range from, for example, 1 to about 50. The inert gas can be continuously flowed to the reaction chamber during the N deposition and treatment cycles. The step of treating can be performed using, for example, the inert gas. The inert gas can comprise argon, helium, nitrogen, or any mixture thereof. The inert gas can be used to ignite a plasma during each carbon material deposition cycle and/or each deposition and treatment cycle. In accordance with examples of the disclosure, during a carbon material deposition cycle, the step of providing a carbon precursor to the reaction chamber occurs before and continues during the step of forming a plasma within the reaction chamber. In accordance with further examples, during a carbon material deposition cycle, the steps of ceasing the flow of the carbon precursor and ceasing the plasma occur at substantially the same time; alternatively, during a carbon material deposition cycle, the step of ceasing the flow of the carbon precursor occurs before the step of ceasing the plasma. In accordance with some examples, the plasma is continuously formed within the reaction chamber during the steps of providing a carbon precursor to the reaction chamber, ceasing the flow of the carbon precursor, and treating the carbon material with activated species. In accordance with additional examples, the plasma is continuously formed within the reaction chamber while repeating one or more carbon material deposition cycles. In accordance with yet further examples, the plasma is continuously formed within the reaction chamber during at least one carbon material deposition cycle and at least one treatment step. In accordance with further examples, during a carbon material deposition cycle, a plasma is continuously formed within the reaction chamber during the steps of providing a carbon precursor to the reaction chamber and ceasing the flow of the carbon precursor. In accordance with further examples, a power (e.g., an RF power) provided to form a plasma is reduced (e.g., just—e.g., within about 1.0 seconds) after ceasing the flow of the carbon precursor. In accordance with additional examples, the power (e.g., RF power) to form a plasma is increased to perform the step of treating the carbon material with activated species. In accordance with various aspects of these embodiments, both the inert gas and the carbon precursor are flowed to the reaction chamber during the step of forming a plasma within the reaction chamber. The inert gas can be continuously flowed to the reaction chamber during the steps of providing a carbon precursor to the reaction chamber and forming a plasma within the reaction chamber. In accordance with various examples of the disclosure, a chemical formula of the carbon precursor is represented by CₓH_{y}N_{z}, wherein x is a natural number of 2 or more, y is a natural number and z is 0 or a natural number. The carbon precursor can include a cyclic structure and/or a compound (e.g., cyclic compound) having at least one double bond. In accordance with further examples, one or more steps are performed at a temperature less than or equal to 100° C.

In accordance with yet further exemplary embodiments of the disclosure, a film structure is formed, at least in part, according to a method described herein. The film structure can include a treated carbon layer that includes 45 atomic % or more carbon. Additionally or alternatively, the film structure can include less than 50 particles, whose detectable size is over 50 nm, on 300 mm wafer, on the surface of the treated carbon layer having a layer thickness of 100 nm or more.

In accordance with yet further exemplary embodiments of the disclosure, a system is provided for performing a method and/or for forming a film structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates scanning transmission electron microscopy images of film structures including a carbon layer.

FIG. 3 illustrates another method in accordance with exemplary embodiments of the disclosure.

FIG. 4 illustrates another method in accordance with exemplary embodiments of the disclosure.

FIG. 5 illustrates-another method in accordance with exemplary embodiments of the disclosure.

FIG. 6 illustrates another method in accordance with exemplary embodiments of the disclosure.

FIG. 7 illustrates another method in accordance with exemplary embodiments of the disclosure.

FIG. 8 illustrates a system in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of depositing materials, to methods of forming (e.g., film) structures, to film structures formed using the methods, and to systems for performing the methods and/or forming the film structures. By way of examples, the methods described herein can be used to fill features, such as gaps (e.g., trenches or vias) on a surface of a substrate with material, such as carbon (e.g., dielectric) material. The terms gap and recess can be used interchangeably.

To mitigate void and/or seam formation during a gap-filling process, deposited carbon material can be initially flowable and flow within the gap to fill the gap. Exemplary structures described herein can be used in a variety of applications, including, but not limited to, cell isolation in 3D cross point memory devices, self-aligned vias, dummy gates, reverse tone patterns, PC RAM isolation, cut hard masks, DRAM storage node contact (SNC) isolation, and the like.

In this disclosure, “gas” can refer to material that is a gas at normal temperature and pressure, a vaporized solid and/or a vaporized liquid, and may be constituted by a single gas or a mixture of gases, depending on the context. A gas other than a process gas, i.e., a gas introduced without passing through a gas distribution assembly, such as a showerhead, other gas distribution device, or the like, may be used for, e.g., sealing a reaction space, which includes a seal gas, such as a rare gas. In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than a precursor, that activates a precursor, modifies a precursor, or catalyzes a reaction of a precursor; a reactant may provide an element (such as O, H, N, C) to a film matrix and become a part of the film matrix when, for example, power (e.g., radio frequency (RF) power) is applied. In some cases, the terms precursor and reactant can be used interchangeably. The term “inert gas” refers to a gas that does not take part in a chemical reaction to an appreciable extent and/or a gas that excites a precursor (e.g., to facilitate polymerization of the precursor) when, for example, power (e.g., RF power) is applied, but unlike a reactant, it may not become a part of a film matrix to an appreciable extent.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various features, such as gaps (e.g., recesses or vias), lines or protrusions, such as lines having gaps formed therebetween, and the like formed on or within or on at least a portion of a layer or bulk material of the substrate. By way of examples, one or more features can have a width of about 10 nm to about 100 nm, a depth or height of about 30 nm to about 1,000 nm, and/or an aspect ratio of about 3.0 to 100.0.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using multiple deposition cycles and/or multiple deposition and treatment cycles.

As used herein, the term “carbon layer” or “carbon material” can refer to a layer whose chemical formula can be represented as including carbon. Layers comprising carbon material can include other elements, such as one or more of nitrogen and hydrogen.

As used herein, the term “structure” can refer to a partially or completely fabricated device structure. By way of examples, a structure can be a substrate or include a substrate with one or more layers and/or features formed thereon.

As used herein, the term “cyclic deposition process” can refer to a vapor deposition process in which deposition cycles, typically a plurality of consecutive deposition cycles, are conducted in a process chamber. Cyclic deposition processes can include cyclic chemical vapor deposition (CVD) and atomic layer deposition processes. A cyclic deposition process can include one or more cycles that include plasma activation of a precursor, a reactant, and/or an inert gas.

In this disclosure, “continuously” can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

A flowability (e.g., an initial flowability) can be determined as follows:

TABLE 1

| bottom/top | |
|---|---|
| ratio (B/T) | Flowability |
| 0 < B/T < 1 | None |
| 1 ≤ B/T < 1.5 | Poor |
| 1.5 ≤ B/T < 2.5 | Good |
| 2.5 ≤ B/T < 3.5 | Very good |
| 3.5 ≤ B/T | Extremely good |

where B/T refers to a ratio of thickness of film deposited at a bottom of a recess to thickness of film deposited on a top surface where the recess is formed, before the recess is filled. Typically, the flowability is evaluated using a wide recess having an aspect ratio of about 1 or less, since generally, the higher the aspect ratio of the recess, the higher the B/T ratio becomes. The B/T ratio generally becomes higher when the aspect ratio of the recess is higher. As used herein, a “flowable” film or material exhibits good or better flowability.

As set forth in more detail below, flowability of film can be temporarily obtained when a volatile hydrocarbon precursor, for example, is polymerized by a plasma and deposits on a surface of a substrate, wherein the gaseous precursor is activated or fragmented by energy provided by plasma gas discharge, so as to initiate polymerization. The resultant polymer material can exhibit temporarily flowable behavior. When a deposition step is complete and/or after a short period of time (e.g., about 3.0 seconds), the film may no longer be flowable, but rather becomes solidified, and thus, a separate solidification process may not be employed.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

Methods in accordance with exemplary embodiments of the disclosure include the steps of providing a substrate within a reaction chamber, providing an inert gas to the reaction chamber, providing a carbon precursor to the reaction chamber, forming a plasma within the reaction chamber to form an initially viscous carbon material on a surface of the substrate, wherein the initially viscous carbon material becomes carbon material, and treating the carbon material with activated species to form treated carbon material. The methods can also include ceasing a flow of the carbon precursor to the reaction chamber and ceasing the plasma.

During the step of providing a substrate within a reaction chamber, the substrate is provided into a reaction chamber of a gas-phase reactor. In accordance with examples of the disclosure, the reaction chamber can form part of a cyclical deposition reactor, such as an atomic layer deposition (ALD) (e.g., PEALD) reactor or chemical vapor deposition (CVD) (e.g., PECVD) reactor. Various steps of methods described herein can be performed within a single reaction chamber or can be performed in multiple reaction chambers, such as reaction chambers of a cluster tool.

During the step of providing a substrate within a reaction chamber, the substrate can be brought to a desired temperature and/or the reaction chamber can be brought to a desired pressure, such as a temperature and/or pressure suitable for subsequent steps. By way of examples, a temperature (e.g., of a substrate or a substrate support) within a reaction chamber can be less than or equal to 100° C. A pressure within the reaction chamber can be from about 200 Pa to about 1,250 Pa. In accordance with particular examples of the disclosure, the substrate includes one or more features, such as recesses.

During the step of providing an inert gas to the reaction chamber, one or more inert gases, such as argon, helium, nitrogen, or any mixture thereof are provided to the reaction chamber. By way of particular examples, the inert gas is or includes helium. A flowrate of the inert gas to the reaction chamber during this step can be from about 500 sccm to about 8,000 sccm. As described in more detail below, the inert gas can be used to ignite a plasma within the reaction chamber, to purge reactants and/or byproducts from the reaction chamber, and/or be used as a carrier gas to assist with delivery of the precursor to the reaction chamber. A power used to ignite and maintain the plasma can range from about 50 W to about 800 W. A frequency of the power can range from about 2.0 MHz to about 27.12 MHz.

During the step of providing a carbon precursor to the reaction chamber, a precursor for forming a layer of carbon material is introduced into the reaction chamber. Exemplary precursors include compounds represented by the formula C_{X}H_{Y}N_{Z}, where x is a natural number greater than or equal to 2, y is a natural number, and z is zero or a natural number. For example, x can range from about 2 to about 15, y can range from about 4 to about 30, and z can range from about 0 to about 10. The precursor can include a chain or cyclic molecule having two or more carbon atoms and one or more hydrogen atoms, such as molecules represented by the formula above. By way of particular examples, the precursor can be or include one or more cyclic (e.g., aromatic) structures and/or compounds having at least one double bond.

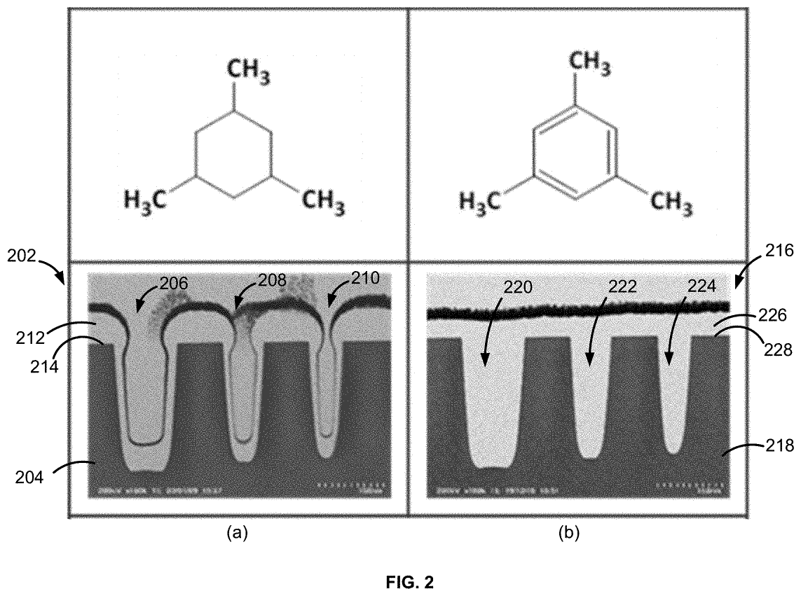

With momentary reference to FIG. 2, FIG. 2(a) illustrates a structure 202 that includes a substrate 204, having gaps 206, 208, and 210 formed therein, and a carbon layer 212 overlying a surface 214 of substrate 204. FIG. 2(b) illustrates a structure 216 that includes a substrate 218, having gaps 220, 222, and 224 formed therein, and a carbon layer 226 overlying a surface 228 of substrate 218. The deposition conditions for structures 202 and 216 were the same, except the precursor used to form structure 202 was 1,3,5, trimethylcyclohexane and the precursor used to form structure 216 was 1,3,5, trimethylbenzene, suggesting that use of precursors with at least one carbon (e.g., carbon-carbon) double bond may be beneficial for filling recesses, while mitigating any void formation.

A flowrate of the carbon precursor from a carbon precursor source to the reaction chamber can vary according to other process conditions. By way of examples, the flowrate can be from about 100 sccm to about 3,000 sccm. Similarly, a duration of each step of providing a carbon precursor to the reaction chamber can vary, depending on various considerations. By way of examples, the duration can range from about 1.0 seconds to about 35.0 seconds.

During the step of forming a plasma within the reaction chamber to form an initially viscous carbon material on a surface of the substrate, the precursor is converted into the initially viscous material using excited species. The initially viscous carbon material can become carbon material—e.g., through further reaction with excited species. The carbon material can be solid or substantially solid.

During the step of ceasing a flow of the carbon precursor to the reaction chamber, a flow of the carbon precursor to the reaction chamber is stopped. In some cases, a flow of the precursor may be reduced and not entirely shut off for various steps.

During the step of ceasing the plasma, a plasma can be extinguished. The step of ceasing can include reducing a power used to produce a plasma.

The step of treating the carbon material with activated species to form treated carbon material includes exposing the carbon material to activated species—e.g., to activated species formed using a plasma. The step of treating can include forming species from an inert gas, such as the inert gas provided during the step of providing an inert gas to the reaction chamber. A power used to form the plasma can range from about 50 W to about 800 W. A frequency of the power can range from about 2.0 MHz to about 27.12 MHz.

In accordance with exemplary aspects of the disclosure, activated species are formed by using a plasma (e.g., radio frequency and/or microwave plasma). A direct plasma and/or a remote plasma can be used to form the activated species. In some cases, an inert gas can be continuously flowed to the reaction chamber and activated species can be periodically formed by cycling the power used to form the plasma. A temperature within a reaction chamber during the step of treating the carbon material can be less than or equal to 100° C. A pressure within a reaction chamber during the species formation for treatment can be from about 200 Pa to about 1,250 Pa. The species formation for treatment step can be formed in the same reaction chamber used for one or more or other steps or can be a separate reaction chamber, such as another reaction chamber of the same cluster tool.

Steps of various methods described herein can overlap and need not be performed in the order noted above. Further, in some cases, various steps or portions thereof can be repeated one or more times prior to a method proceeding to the next step.

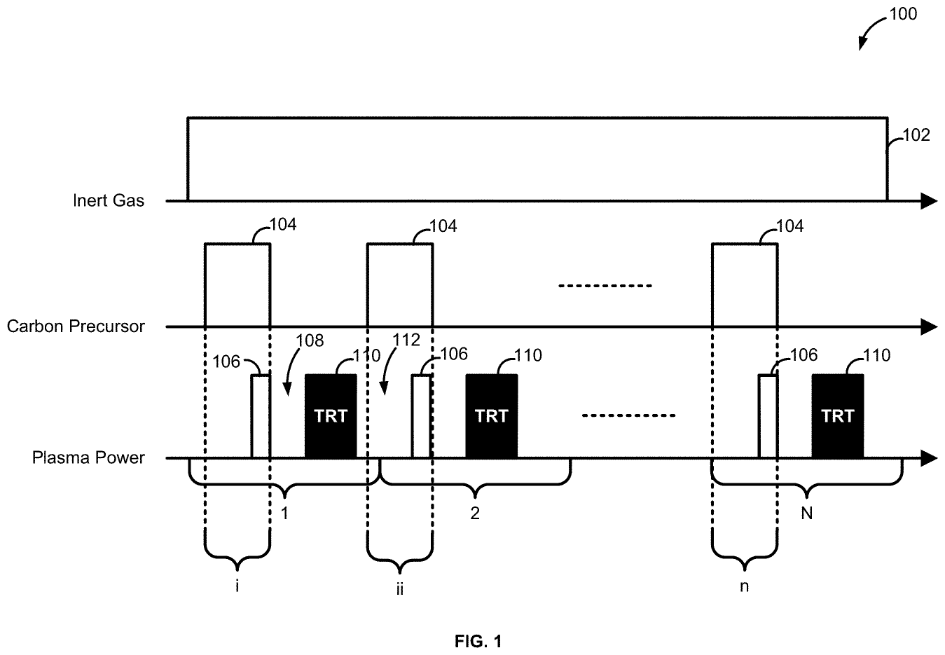

FIGS. 1 and 3-7 illustrate examples of pulse timing sequences for methods in accordance with exemplary embodiments of the disclosure. The figures schematically illustrate inert gas, carbon precursor, and plasma power pulses, where gases and/or plasma power are provided to a reactor system for a pulse period. The width of the pulses may not necessarily be indicative of an amount of time associated with each pulse; the illustrated pulse can illustrate relative start times of the various pulses. Similarly, a height may not necessarily be indicative of a specific amplitude or value, but can show relative high and low values. These examples are merely illustrative and are not meant to limit the scope of the disclosure or claims.

FIG. 1 illustrates a method 100. Method 100 includes a plurality of carbon material deposition cycles i, ii . . . n and a plurality of deposition and treatment cycles 1, 2 . . . N. In accordance with examples of these embodiments, n and N can range from about 1 to about 50.

Method 100 can include continuously supplying an inert gas to the reaction chamber during one or more carbon material deposition cycles i, ii . . . n and/or one or more deposition and treatment cycles 12 . . . N. In the illustrated example, the inert gas is provided to the reaction chamber for a pulse period 102, which begins prior to a first (i) deposition cycle and ends after the last (N) deposition and treatment cycle. Pulse periods can be referred to simply as pulses.

After pulse period 102 is initiated, a carbon precursor is provided to the reaction chamber for a pulse period 104. Pulse period 104 can range from, for example, about 1.0 seconds to about 35.0 seconds. Each pulse period 104 can be the same or vary in time.

After the flow of the carbon precursor to the reaction chamber has started, power to form a plasma is provided for a pulse period 106. Thus, in the illustrated example, both the inert gas and the carbon precursor are provided to the reaction chamber when the plasma is ignited/formed. Pulse period 106 can range from, for example, about 1.0 second to about 30.0 seconds. Each pulse period 106 can be the same or vary in time.

As illustrated in this example, pulse period 104 and pulse period 106 may cease at about or substantially the same time (e.g., within 10, 5, 2, 1, or 0.5 percent of each other). Once the flow of the carbon precursor to the reaction chamber and the plasma power have ceased, the reaction chamber can be purged for a purge period or pulse period 108. Pulse period 108 can range from, for example, about 5.0 seconds to about 30.0 seconds. Each pulse period 108 can be the same or vary in time.

A power (e.g., applied to electrodes) during step 106 can range from about 100 W to about 800 W. A frequency of the power can range from about 2.0 MHz to about 27.12 MHz.

After pulse period 108, the plasma power can be increased to a desired level for treating the carbon material with activated species for a pulse period 110. The power level and pressure within the reaction chamber can be as described above. Pulse period 110 can range from, for example, about 1.0 second to about 30.0 seconds. Each pulse period 110 can be the same or vary in time.

After the step of treating the carbon material with activated species fora pulse period 110, the reaction chamber can be purged for a pulse period 112. Pulse period 112 can range from, for example, about 10.0 seconds to about 70.0 seconds. Each pulse period 112 can be the same or vary in time.

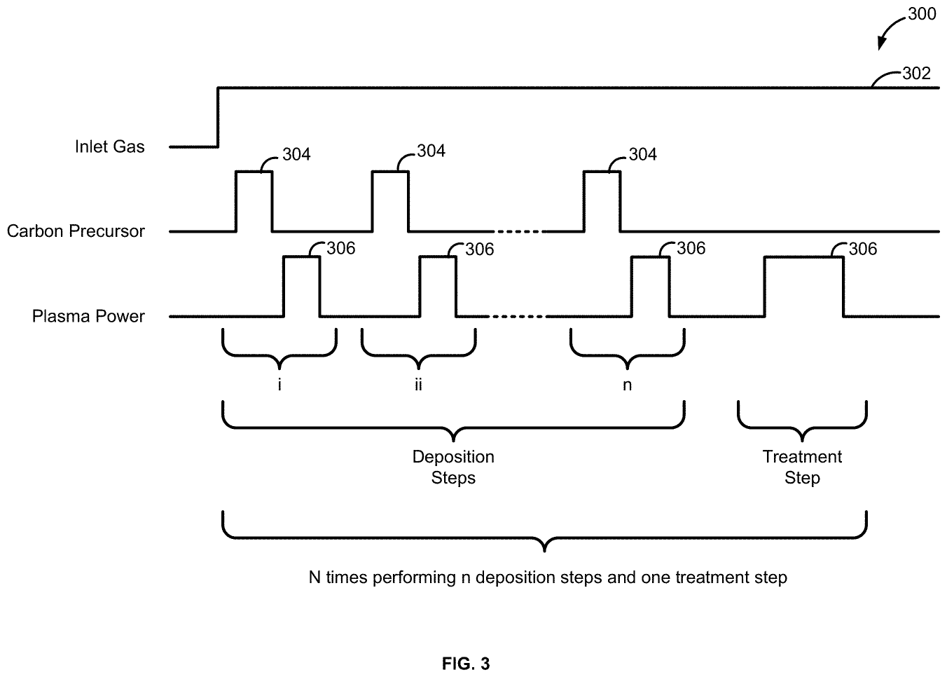

FIG. 3 illustrates another method 300. Similar to method 100, method 300 includes a plurality of carbon material deposition cycles i, ii . . . n and one or more deposition and one treatment step or cycle 1 . . . N. In accordance with examples of these embodiments, n can range from about 1 to about 50 and N can range from about 1 to about 50.

Method 300 can include continuously supplying an inert gas to the reaction chamber during one or more carbon material deposition cycles i, ii . . . n and/or one or more deposition and one treatment steps 1, 2, 3, 4 . . . N. In the illustrated example, the inert gas is provided to the reaction chamber for a pulse period 302, which begins prior to a first (i) deposition cycle and can end after the last (N) deposition and treatment cycle.

After pulse period 302 is initiated, a carbon precursor is provided to the reaction chamber for a pulse 304. Pulse period 304 can range from, for example, about 1.0 seconds to about 5.0 seconds.

After the flow of the carbon precursor to the reaction chamber has started, power to form a plasma is provided for a pulse period 306. In the illustrated example, the flow of the carbon precursor is ceased prior to a plasma being ignited/formed. Although this method may be suitable for some applications, method 300 may result in undesirably high—e.g., much greater than 50 particles, whose detectable size is over 50 nm, on 300 mm wafer, on the surface of the treated carbon layer having a layer thickness of 100 nm or more.

In contrast, FIGS. 1 and 4-7 illustrate methods to deposit carbon material with relatively low—e.g., less than 50, 40, 30, 10, or 5 particles, whose detectable size is over 50 nm, on 300 mm wafer, on the surface of the treated carbon layer having a layer thickness of 100 nm or more. One technique to reduce a number of particles on a surface during a method of forming a structure as described herein includes maintaining a power for plasma formation while the carbon precursor flow ceases.

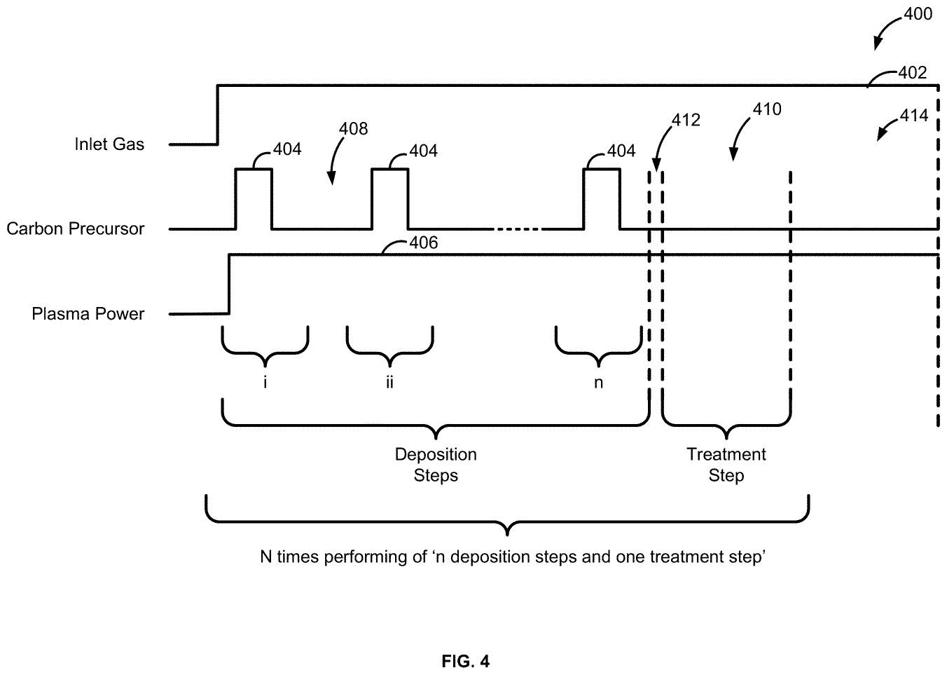

FIG. 4 illustrates a method 400 in accordance with examples of the disclosure.

Method 400 includes a plurality of carbon material deposition cycles i, ii . . . n and one or more deposition and one treatment steps 1 . . . N. In accordance with examples of these embodiments, n can range from about 1 to about 50 and N can range from about 1 to about 50.

Method 400 can include continuously supplying an inert gas to the reaction chamber during one or more carbon material deposition cycles i, ii . . . n and/or one or more deposition and one treatment cycles 1 . . . N. In the illustrated example, the inert gas is provided to the reaction chamber for a pulse period 402, which begins prior to a first (i) deposition cycle and ends after the last (N) deposition and treatment cycle.

After pulse 402 is initiated, power to form a plasma is provided for a pulse period 406. The inert gas can be used to ignite the plasma. The plasma can be continuous for the duration of pulse period 406. Pulse period 406 can range from, for example, about 3.0 seconds to about 3,600.0 seconds. A power (e.g., applied to electrodes) during pulse period 406 can range from about 100 W to about 800 W. A frequency of the power can range from about 2.0 MHz to about 27.12 MHz.

Once the plasma is formed, a carbon precursor pulse period 404 can begin. In the illustrated example, both the inert gas and the carbon precursor are provided to the reaction chamber during pulse period 404. At the end of pulse period 404, the inert gas pulse and plasma power pulse continue. This is thought to facilitate a reduction of particles on a surface of a substrate or layer thereon that would otherwise form on a surface during a carbon material deposition cycle—such as particles that can form during method 300. A time duration of pulse period 404 can range from, for example, about 1.0 second to about 30.0 seconds. Pulse periods 404 can be performed a number of n times prior to a treatment pulse 410.

The reaction chamber can be purged for a pulse period 408. During this time, power for plasma formation can be continuously supplied to the reactor system. Similarly, after n carbon material deposition cycles, the reaction chamber can be purged for a pulse period 412. And, after a treatment step 410—i.e., after a deposition and treatment cycle N, the reaction chamber can be purged for a pulse period 414. If desired, the next deposition and treatment cycle can then begin. As above, times of one or more pulses can be the same or vary.

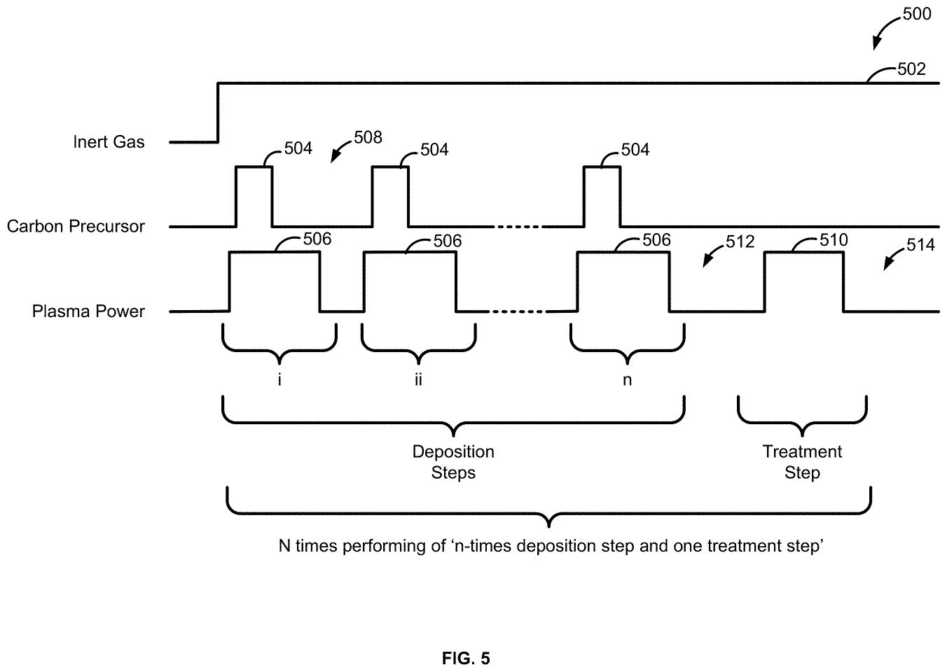

FIG. 5 illustrates another method 500 in accordance with examples of the disclosure. Method 500 is similar to method 400, except plasma power is pulsed for each carbon material deposition cycle i, ii . . . n.

Method 500 can include continuously supplying an inert gas to the reaction chamber during one or more carbon material deposition cycles i, ii . . . n and/or one or more deposition and one treatment cycles 1, 2, 3, 4 . . . N. In the illustrated example, the inert gas is provided to the reaction chamber for a pulse period 502, which begins prior to a first deposition cycle and ends after the last (N) deposition and treatment cycle.

After pulse period 502 is initiated, power to form a plasma is provided for a pulse period 506. The inert gas can be used to ignite the plasma. In the illustrative example, pulse period 506 continues after ceasing of a carbon precursor flow (pulse period 504). A pulse period 506 can range from, for example, about 1.0 seconds to about 20.0 seconds. A power (e.g., applied to electrodes) during pulse period 506 can range from about 100 W to about 800 W. A frequency of the power can range from about 2.0 MHz to about 27.12 MHz.

Once the plasma is formed, a carbon precursor pulse period 504 can begin. In the illustrated example, both the inert gas and the carbon precursor are provided to the reaction chamber during pulse period 504. At the end of pulse period 504, the inert gas pulse and plasma power pulse continue. Again, this is thought to facilitate a reduction of particles that would otherwise form on a surface of a substrate during a carbon material deposition cycle. A time duration of pulse period 504 can range from, for example, about 1.0 second to about 30.0 seconds. Pulse periods 504 and pulse periods 506 can be performed a number of n times prior to a treatment pulse period 510.

During a treatment step, inert gas pulse period 502 continues and power to form a plasma is again increased to a desired level for a pulse period 510. A power (e.g., applied to electrodes) during pulse period 510 can range from about 100 W to about 800 W. A frequency of the power can range from about 2.0 MHz to about 27.12 MHz. A time duration of pulse period 510 can range from, for example, about 1.0 second to about 30.0 seconds.

Between pulse periods 504, the reaction chamber can be purged for a pulse period 508. During at least a portion of this time, power for plasma formation can be supplied to the reactor system. Similarly, after n carbon material deposition cycles, the reaction chamber can be purged for a pulse period 512. During at least a portion of pulse period 512, power for plasma formation can be supplied to the reactor system. After treatment step 510—i.e., after a deposition and treatment cycle N, the reaction chamber can be purged for a pulse period 514. If desired, the next deposition and treatment cycle can then begin. As above, times of one or more pulses for cycles can be the same or vary.

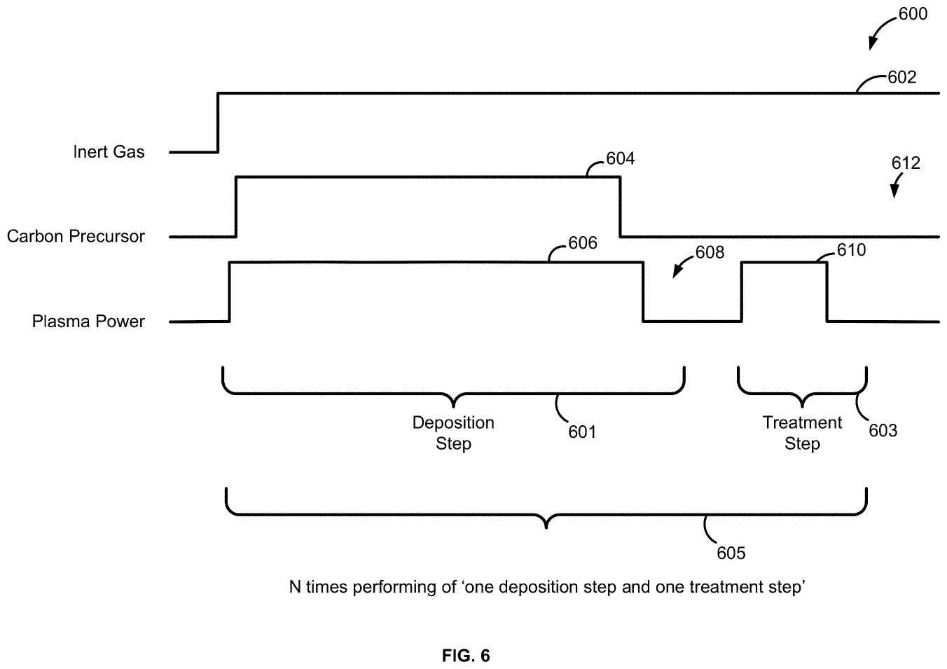

FIG. 6 illustrates a method 600 with one carbon material deposition cycle 601 followed by a treatment step 603 for each deposition and treatment cycle 605.

Similar to methods 400 and 500, method 600 can include continuously supplying an inert gas to the reaction chamber during a carbon material deposition cycle 601 and deposition and treatment cycle 605. One-time deposition step and one-time treatment can be performed N times. N can range from about 1 to about 50. In the illustrated example, the inert gas is provided to the reaction chamber for a pulse period 602, which begins prior to deposition cycle 601 and ends after deposition and treatment cycle 605.

After pulse period 602 is initiated, power to form a plasma is provided for a pulse period 606. The inert gas can be used to ignite the plasma. In the illustrative example, pulse period 606 continues after ceasing of a carbon precursor flow (pulse period 604). A pulse period 606 can range from, for example, about 3.0 seconds to about 1,000.0 seconds. A power (e.g., applied to electrodes) during pulse period 604 can range from about 100 W to about 800 W. A frequency of the power can range from about 2.0 MHz to about 27.12 MHz.

Once the plasma is formed, a carbon precursor pulse period 604 can begin. In the illustrated example, both the inert gas and the carbon precursor are provided to the reaction chamber during pulse period 604. At the end of pulse period 604, the inert gas pulse and plasma power pulse continue. Again, this is thought to facilitate a reduction of particles that would otherwise form on a surface of a substrate during a carbon material deposition cycle. A time duration of pulse period 604 can range from, for example, about 1.0 second to about 30.0 seconds.

During treatment step 603, inert gas pulse period 602 continues and power to form a plasma is again increased to a desired level. A power (e.g., applied to electrodes) during pulse period 610 can range from about 100 W to about 800 W. A frequency of the power can range from about 2.0 MHz to about 27.12 MHz. A time duration of pulse period 610 can range from, for example, about 1.0 second to about 30.0 seconds.

After pulse period 604, the reaction chamber can be purged for a pulse period 608. During at least a portion of this time, power for plasma formation can be supplied to the reactor system, such that the power is supplied while flow of the carbon precursor is ceased. Similarly, after carbon material deposition and treatment cycle 605, the reaction chamber can be purged for a pulse period 612. During at least a portion of pulse period 612, power for plasma formation can be supplied to the reactor system. As above, the time for various pulses of cycles can be the same or differ.

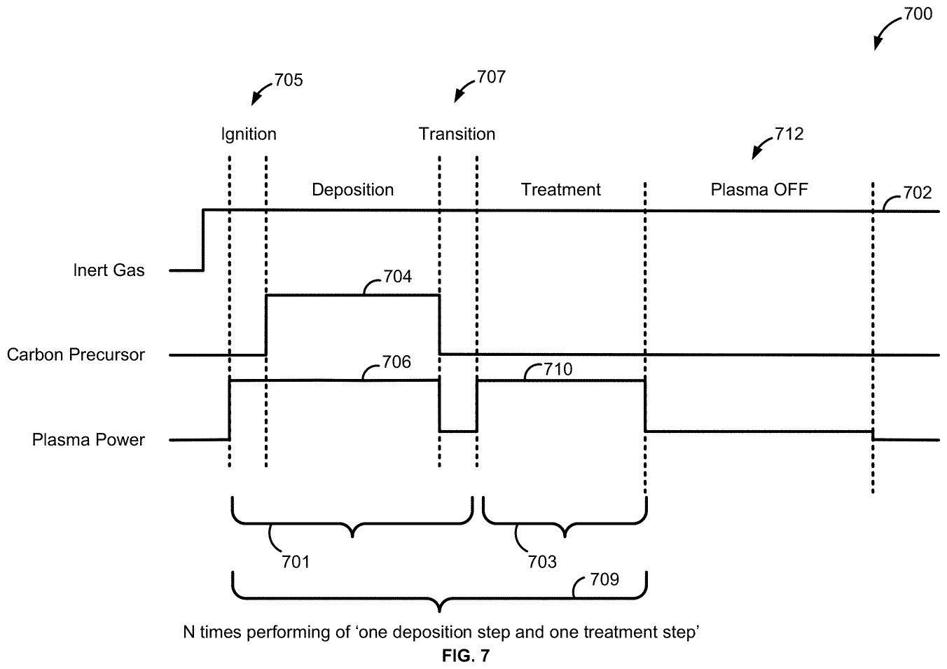

FIG. 7 illustrates a method 700 in accordance with yet further examples of the disclosure. Method 700 can be similar to method 100, with method 700 showing additional ignition and transition steps. Any of the methods described herein can include ignition and/or transition steps.

Similar to method 100, method 700 can include continuously supplying an inert gas to the reaction chamber during one carbon material deposition cycles 701 and/or one deposition and treatment cycles 709. One-time deposition step and one-time treatment is performed N times. N can range from about 1 to about 50. In the illustrated example, the inert gas is provided to the reaction chamber for a pulse period 702, which begins prior to deposition cycle 701 and ends after deposition and treatment cycle 709.

After pulse period 702 is initiated, power to form a plasma is provided for a pulse period 706. The inert gas can be used to ignite the plasma. In the illustrative example, pulse period 706 ceases at about the same time or after ceasing of a carbon precursor flow (pulse period 704). A pulse period 706 can range from, for example, about 3.0 seconds to about 40.0 seconds. A power (e.g., applied to electrodes) during pulse period 706 can range from about 100 W to about 800 W. A frequency of the power can range from about 2.0 MHz to about 27.12 MHz.

Upon providing power for a plasma, an ignition period 705 begins. Ignition period 705 can continue until a plasma is stabilized and/or until carbon precursor pulse period 704 is initiated. A duration of ignition period 705 can range from about 2.0 second to about 10.0 seconds.

Once the plasma is formed, a carbon precursor pulse period 704 can begin. In the illustrated example, both the inert gas and the carbon precursor are provided to the reaction chamber during pulse period 704. At the end of pulse period 704 and/or pulse period 706, the inert gas continues for a transition period 707. A time duration of pulse period 704 can range from, for example, about 1.0 second to about 30.0 seconds. A duration of ignition period 705 can range from about 2.0 second to about 10.0 seconds.

At the end of transition period 707, power for the plasma is increased to again form a plasma. During a treatment step 703 (pulse period 710), inert gas pulse period 702 continues and power to form a plasma is maintained at a desired level. A power (e.g., applied to electrodes) during pulse period 710 can range from about 100 W to about 800 W. A frequency of the power can range from about 2.0 MHz to about 27.12 MHz. A time duration of pulse period 710 can range from, for example, about 1.0 second to about 30.0 seconds.

After pulse periods 704, the reaction chamber can be purged during transition period 707. During at least a portion of this time, power for plasma formation can be supplied to the reactor system, such that the power is supplied while flow of the carbon precursor is ceased. Similarly, after carbon material deposition cycle and treatments cycle 709, the reaction chamber can be purged for a pulse period 712. During at least a portion of pulse period 712, power for plasma formation can be turned off. The duration of each of the pulses for different cycles can be the same or can vary.

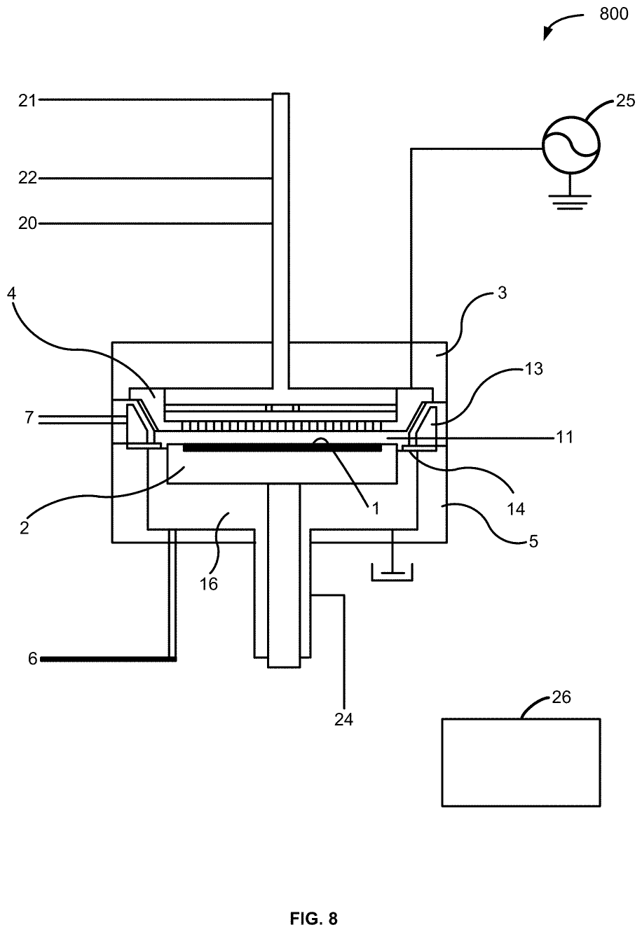

FIG. 8 illustrates a reactor system 800 in accordance with exemplary embodiments of the disclosure. Reactor system 800 can be used to perform one or more steps or sub steps as described herein and/or to form one or more structures or portions thereof as described herein.

Reactor system 800 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz) from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 800 can include any suitable number of gas lines.

In reaction chamber 3, a circular duct 13 with an exhaust line 7 is provided, through which gas in the interior 11 of the reaction chamber 3 can be exhausted. Additionally, a transfer chamber 5, disposed below the reaction chamber 3, is provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone is provided (a gate valve through which a wafer is transferred into or from the transfer chamber 5 is omitted from this figure). The transfer chamber is also provided with an exhaust line 6. In some embodiments, the deposition and treatment steps are performed in the same reaction space, so that two or more (e.g., all) of the steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber, and can carry the precursor gas in pulses by switching between the main line and the detour line, without substantially fluctuating pressure of the reaction chamber.

A skilled artisan will appreciate that the apparatus includes one or more controller(s) 26 programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a structure, the method comprising the steps of:
providing a substrate within a reaction chamber, the substrate comprising one or more recesses;
providing an inert gas to the reaction chamber for plasma ignition;
providing a carbon precursor to the reaction chamber;
forming a plasma within the reaction chamber to form an initially viscous carbon material on a surface of the substrate, wherein the initially viscous carbon material becomes carbon material;
ceasing a flow of the carbon precursor to the reaction chamber;
ceasing the plasma; and
treating the carbon material with activated species to form treated carbon material.

2. The method of claim 1, wherein the steps of:
providing a carbon precursor to the reaction chamber;
forming a plasma within the reaction chamber to form an initially viscous carbon material on a surface of the substrate;
ceasing a flow of the carbon precursor;
ceasing the plasma; and
treating the carbon material with activated species are performed a number of N times to fill the one or more recesses.

3. The method of claim 2, wherein N ranges from about 1 to about 50.

4. The method of claim 1, wherein the step of treating comprises igniting a plasma using the inert gas within the reaction chamber.

5. The method of claim 1, wherein, during a carbon material deposition cycle, the step of providing a carbon precursor to the reaction chamber occurs before and continues during the step of forming a plasma within the reaction chamber.

6. The method of claim 1, wherein, during a carbon material deposition cycle, the steps of ceasing the flow of the carbon precursor and ceasing the plasma occur at substantially the same time.

7. The method of claim 1, wherein, during a carbon material deposition cycle, the step of ceasing the flow of the carbon precursor occurs before the step of ceasing the plasma.

8. The method of claim 1, wherein an RF power provided to form a plasma is reduced after ceasing the flow of the carbon precursor.

9. The method of claim 1, wherein an RF power to form a plasma is increased to perform the step of treating the carbon material with activated species.

10. The method of claim 1, wherein both the inert gas and the carbon precursor are flowed to the reaction chamber during the step of forming a plasma within the reaction chamber.

11. The method of claim 1, wherein the inert gas is continuously flowed to the reaction chamber during the steps of providing a carbon precursor to the reaction chamber and forming a plasma within the reaction chamber.

12. The method of claim 1, wherein a deposition and treatment cycle includes:
performing a carbon material deposition cycle one or more times; and then
treating the carbon material with activated species,
wherein the deposition and treatment cycle is performed a number of times for N deposition and one treatment step, and
wherein the inert gas is continuously flowed to the reaction chamber during the N deposition and one treatment step.

13. The method of claim 1, wherein the steps of forming a plasma within the reaction chamber to form an initially viscous carbon material on a surface of the substrate and ceasing the plasma are repeated a number of times prior to the step of treating the carbon material with activated species.

14. The method of claim 1, wherein, during a carbon material deposition cycle, a plasma is continuously formed within the reaction chamber during the steps of providing a carbon precursor to the reaction chamber and ceasing the flow of the carbon precursor.

15. The method of claim 1, wherein a plasma is continuously formed within the reaction chamber during the steps of providing a carbon precursor to the reaction chamber, ceasing the flow of the carbon precursor, and treating the carbon material with activated species.

16. The method of claim 1, wherein a plasma is continuously formed within the reaction chamber while repeating one or more carbon material deposition cycles.

17. The method of claim 1, wherein a plasma is continuously formed within the reaction chamber during at least one carbon material deposition cycle and at least one treatment step.

18. The method of claim 1, wherein, during a carbon material deposition cycle, a duration of the step of forming a plasma within the reaction chamber to form the initially viscous carbon material is between about 1.0 second and about 30.0 seconds.

19. The method of claim 1, wherein, during a deposition and treatment cycle, a duration of the step treating the carbon material with activated species is between about 1.0 seconds and about 30.0 seconds.

20. The method of claim 1, wherein the inert gas comprises argon, helium, nitrogen, or any mixture thereof.

21. The method of claim 1, wherein a chemical formula of the carbon precursor is represented by CₓH_{y}N_{z}, wherein x is a natural number of 2 or more, y is a natural number and z is 0 or a natural number.

22. The method of claim 1, wherein the carbon precursor comprises a cyclic structure having at least one double bond.

23. The method of claim 1, wherein a temperature within the reaction chamber during the steps of:
providing the carbon precursor to the reaction chamber;
forming the plasma within the reaction chamber to form the initially viscous carbon material on a surface of the substrate;
ceasing the flow of the carbon precursor;
ceasing the plasma; and
treating the carbon material with activated species is less than or equal to 100° C.

24. A film structure formed according to the method of claim 1.

25. The film structure of claim 24, wherein the treated carbon layer comprises 45 atomic % or more carbon.

26. The film structure of claim 25, wherein the structure comprises less than 50 particles, whose detectable size is over 50 nm, on 300 mm wafer, on the surface of the treated carbon layer having a layer thickness of 100 nm or more.

27. A system for performing the steps of claim 1.

28. A system for forming the structure according to claim 24.
